(19) United States
(12) Patent Application Publication
(10) Pub. No.: US 2026/0120729 A1
(43) Pub. Date: Apr. 30, 2026

(54) SEMICONDUCTOR MEMORY DEVICE AND ELECTRONIC SYSTEM INCLUDING THE SAME

(71) Applicant: Samsung Electronics Co., Ltd., Suwon-si (KR)

(72) Inventors: Seungmin SONG, Suwon-si (KR); Seo-Goo KANG, Suwon-si (KR); Kyungdong KIM, Suwon-si (KR); Kohji KANAMORI, Suwon-si (KR); Jeehoon HAN, Suwon-si (KR)

(21) Appl. No.: 19/176,348

(22) Filed: Apr. 11, 2025

(30) Foreign Application Priority Data
Oct. 24, 2024 (KR) 10-2024-0146308

(51) Int. Cl. G11C 5/06; H01L 23/00; H01L 25/18; H10B 43/10; H10B 43/27; H10B 43/35; H10B 43/40; H10B 80/00; H10D 80/30

(52) U.S. Cl. CPC G11C 5/063; H10B 43/10; H10B 43/27; H10B 43/35; H10B 43/40; H10B 80/00; H10D 80/30; H10W 90/00; H10W 90/20; H10W 90/732; H10W 90/734; H10W 90/752; H10W 90/754; H10W 90/792

(57) ABSTRACT

A semiconductor device includes a first mold structure including a plurality of first gate electrodes on a first substrate, a plurality of first string gate electrodes on the plurality of first gate electrodes, a first string gate contact extending into a first interlayer insulating film, a second mold structure including a plurality of second gate electrodes on a second substrate, a plurality of second string gate electrodes on the plurality of second gate electrodes, a second string gate contact extending into a second interlayer insulating film, and a first through via extending into the second substrate and the second mold structure and electrically connected to the first string gate contact and the second string gate contact.

### CROSS-REFERENCE TO RELATED APPLICATION

This application claims priority to Korean Patent Application No. 10-2024-0146308, filed in the Korean Intellectual Property Office on Oct. 24, 2024, the entire contents of which are hereby incorporated by reference.

### TECHNICAL FIELD

The present disclosure relates to a semiconductor memory device and an electronic system including the same.

### BACKGROUND OF THE INVENTION

There is a need for a semiconductor memory device capable of storing high-capacity data in an electronic system that requires data storage. Accordingly, ways to increase the data storage capacity of semiconductor memory devices are being studied. For example, one method for increasing the data storage capacity of a semiconductor device has been proposed, which includes a semiconductor device including three-dimensional arrangement of memory cells.

### SUMMARY OF THE INVENTION

In order to solve one or more problems (e.g., the problems described above and/or other problems not explicitly described herein), the present disclosure provides a semiconductor memory device with improved electrical characteristics and reliability.

In order to solve one or more problems (e.g., the problems described above and/or other problems not explicitly described herein), the present disclosure also provides an electronic system with improved electrical characteristics and reliability.

According to some embodiments of the present disclosure, by forming the first through via that electrically connects a first string gate electrode and a second string gate electrode, the electrical characteristics and integration density of the semiconductor memory device may be improved.

According to some embodiments of the present disclosure, a semiconductor memory device may include a first substrate including a first surface and a second surface opposite the first surface, a first mold structure including a plurality of first gate electrodes on the second surface of the first substrate and a plurality of first string gate electrodes on the plurality of first gate electrodes, a first interlayer insulating film on the first mold structure, a first string gate contact extending into the first interlayer insulating film and electrically connected to one of the plurality of first string gate electrodes, a second substrate on the first interlayer insulating film and including a third surface opposite to the second surface, and a fourth surface opposite to the third surface, a second mold structure including a plurality of second gate electrodes on the fourth surface of the second substrate and a plurality of second string gate electrodes on the plurality of second gate electrodes, a second interlayer insulating film on the second mold structure, a second string gate contact extending into the second interlayer insulating film and electrically connected to one of the plurality of second string gate electrodes, and a first through via extending into the second substrate and the second mold structure in a first direction perpendicular to the fourth surface of the second substrate and electrically connected to the first string gate contact and the second string gate contact.

According to some embodiments of the present disclosure, a semiconductor memory device may include a first substrate, a first mold structure including a plurality of first gate electrodes and a plurality of first string gate electrodes on the first substrate, a first interlayer insulating film on the first mold structure, a first string gate contact extending into the first interlayer insulating film and electrically connected to one of the plurality of first string gate electrodes, a second substrate on the first interlayer insulating film and including a cell array region, an extension region, and a selection string region between the cell array region and the extension region, a second mold structure including a plurality of second gate electrodes and a plurality of second string gate electrodes on the second substrate, the plurality of second string gate electrodes comprise a staircase shape of steps on the selection string region and comprising respective pad portions, a second interlayer insulating film on the second mold structure, a second string gate contact on the one of the pad portions of the one of the plurality of second string gate electrodes, the second string gate contact extending into the second interlayer insulating film, and electrically connected to one of the plurality of second string gate electrodes, a first through via extending into the second substrate and the second mold structure and electrically connecting the first string gate contact and the second string gate contact, and a first word line contact on the extension region, extending through a portion of the second mold structure, and electrically connected to one of the plurality of second gate electrodes.

According to some embodiments of the present disclosure, a electronic system may include a main substrate, a semiconductor memory device on the main substrate including a peripheral circuit structure and a cell structure on the peripheral circuit structure, and a controller on the main substrate and electrically connected to the semiconductor memory device, wherein the cell structure includes, a first substrate including a first surface and a second surface opposite the first surface, a first mold structure including a plurality of first gate electrodes on the second surface of the first substrate, and a plurality of first string gate electrodes on the plurality of first gate electrodes, a first interlayer insulating film on the first mold structure, a first string gate contact extending into the first interlayer insulating film and electrically connected to one of the plurality of first string gate electrodes, a second substrate on the first interlayer insulating film and including a third surface opposite to the second surface, and a fourth surface opposite to the third surface, a second mold structure including a plurality of second gate electrodes on the fourth surface of the second substrate, and a plurality of second string gate electrodes on the plurality of second gate electrodes, the plurality of second string gate electrodes comprise a staircase shape of steps and comprising respective pad portions, a second interlayer insulating film on the second mold structure, a second string gate contact on one of the pad portions of the one of the plurality of second string gate electrodes, the second string gate contact extending into the second interlayer insulating film and electrically connected to one of the plurality of second string gate electrodes, and a first through via extending into the second substrate and the second mold structure, extending in a direction perpendicular to the fourth surface of the second substrate and electrically connected to the first string gate contact and the second string gate contact.

### BRIEF DESCRIPTION OF THE DRAWINGS

The above and other embodiments and features of the present disclosure will become more apparent by describing in detail example embodiments thereof with reference to the attached drawings, in which:

FIG. 1 is an example plan view provided to explain a semiconductor memory device according to some embodiments;

FIG. 2 is a cross-sectional view taken along line A-A of FIG. 1;

FIG. 3 is an enlarged view provided to explain a region Q1 of FIG. 2;

FIG. 4 is a cross-sectional view taken along line B-B of FIG. 1;

FIG. 5 is an enlarged view provided to explain a region Q2 of FIG. 4;

FIG. 6 is an enlarged view provided to explain a region Q3 of FIG. 4;

FIG. 7 is a cross-sectional view taken along line C-C of FIG. 1;

FIG. 8 is an example plan view provided to explain a semiconductor memory device according to some embodiments;

FIG. 9 is a cross-sectional view taken along line B-B of FIG. 8;

FIG. 10 is a cross-sectional view taken along the line B-B of FIG. 8.

FIG. 11 is an example plan view provided to explain a semiconductor memory device according to some embodiments;

FIG. 12 is a cross-sectional view taken along line B-B of FIG. 11;

FIG. 13 is an example plan view provided to explain a semiconductor memory device according to some embodiments;

FIG. 14 is a cross-sectional view taken along line B-B of FIG. 13;

FIGS. 15 and 16 are example diagrams provided to explain a semiconductor memory device according to some embodiments;

FIGS. 17 and 18 are example diagrams provided to explain a semiconductor memory device according to some embodiments;

FIG. 19 is an example block diagram provided to explain an electronic system according to some embodiments;

FIG. 20 is a perspective view provided as an example to explain an electronic system according to some embodiments;

FIG. 21 is a schematic cross-sectional view taken along line V-V of FIG. 20.

### DETAILED DESCRIPTION

In the present disclosure, terms such as first, second, etc. may be used to describe various devices or components, but the devices or components are not limited by these terms. It should be understood that these terms are only used to distinguish one element or component from another element or component. The first element or component mentioned below may be the second element or component within the technical idea of the present disclosure.

The term “and/or” includes any and all combinations of one or more of the associated listed items. The term “connected” may be used herein to refer to a physical and/or electrical connection. As used herein, a “level” of an element or component may refer to a distance of the element or component (or a sublayer of a layer structure including the element or component therein) from a reference layer or surface. Components or layers described with reference to “overlap” in a particular direction may be at least partially obstructed by one another when viewed along a line extending in the particular direction or in a plane perpendicular to the particular direction. The term “surrounding” or “covering” or “filling” as may be used herein may not require completely surrounding or covering or filling the described elements or layers, but may, for example, refer to partially surrounding, extending around, or covering or filling the described elements or layers, for example, with voids or other spaces throughout.

It will be understood that spatially relative terms such as ‘on,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

A semiconductor memory device and an electronic system including the semiconductor memory device according to some embodiments of the present disclosure will be described in detail with reference to the drawings.

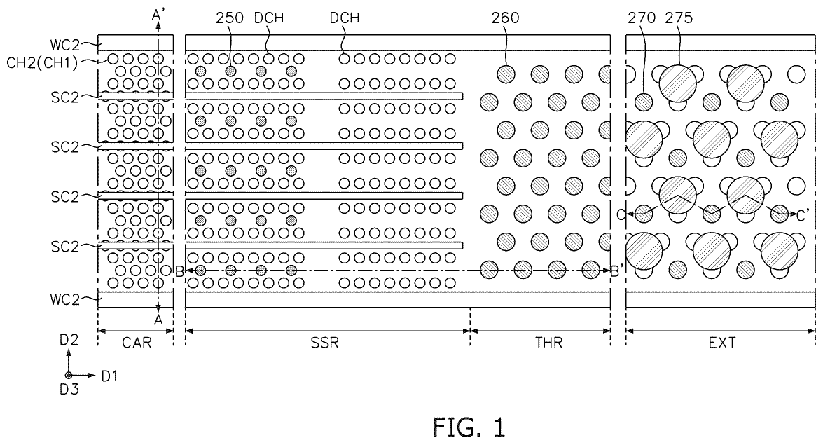

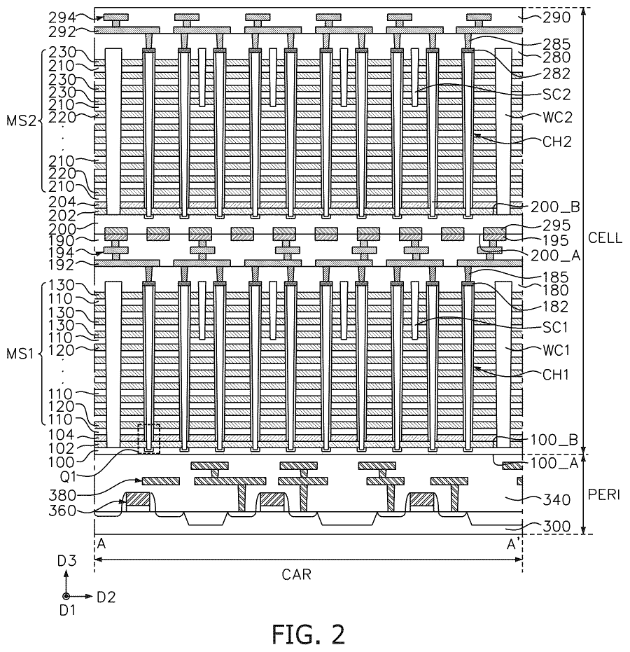

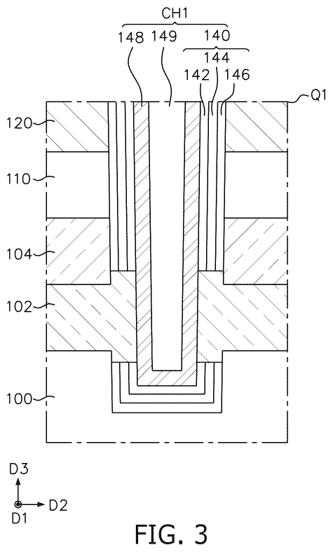

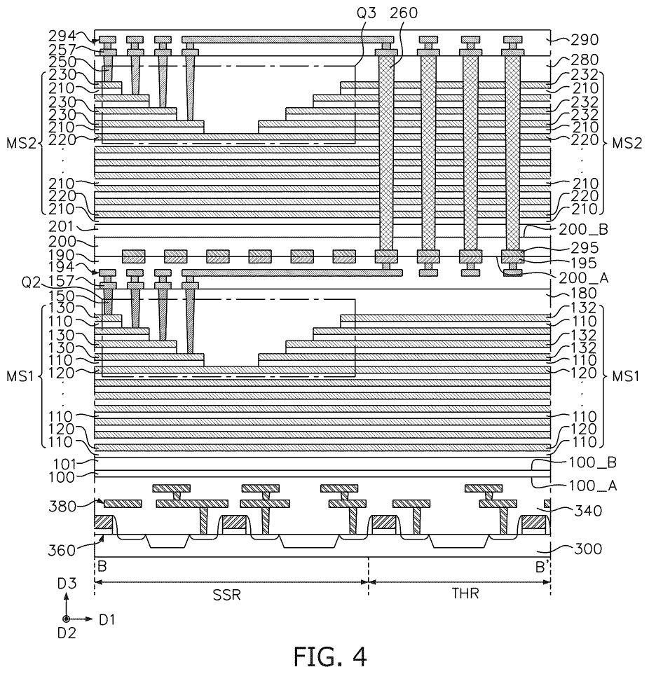

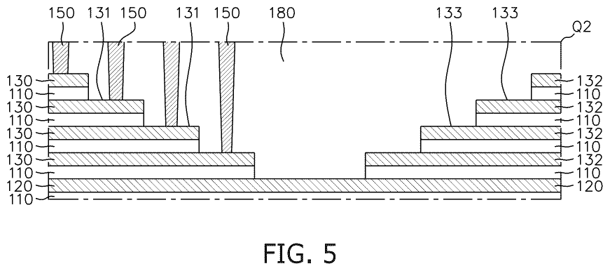

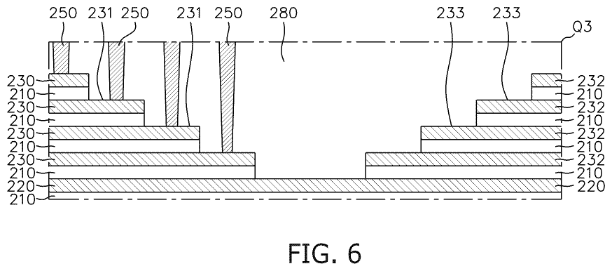

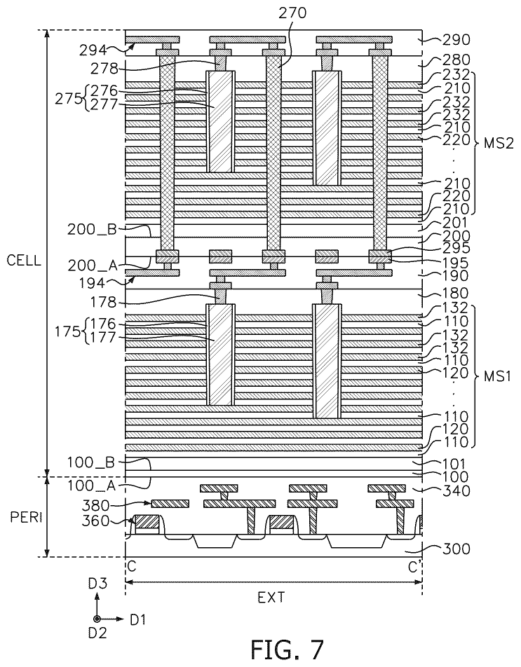

FIG. 1 is an example plan view provided to explain a semiconductor memory device according to some embodiments. FIG. 2 is a cross-sectional view taken along line A-A of FIG. 1. FIG. 3 is an enlarged view provided to explain a region Q1 of FIG. 2. FIG. 4 is a cross-sectional view taken along line B-B of FIG. 1. FIG. 5 is an enlarged view provided to explain a region Q2 of FIG. 4. FIG. 6 is an enlarged view provided to explain a region Q3 of FIG. 4. FIG. 7 is a cross-sectional view taken along line C-C of FIG. 1.

Referring to FIGS. 1 to 7, the semiconductor memory device according to some embodiments may include a cell structure CELL and a peripheral circuit structure PERI.

The cell structure CELL may include a first substrate 100, a first insulating substrate 101, a first string gate contact 150, a first word line contact 175, a first interlayer insulating film 180, a first wiring insulating film 190, a first channel contact 185, a first bit line 192, a first wiring structure 194, a first bonding pad 195, a second substrate 200, a second string gate contact 250, a first through via 260, a second through via 270, a second word line contact 275, a second interlayer insulating film 280, a second channel contact 285, a second wiring insulating film 290, a second bit line 292, a second wiring structure 294, a second bonding pad 295, a first mold structure MS1, a second mold structure MS2, a first channel structure CH1, a second channel structure CH2, a first block separation pattern WC1, a second block separation pattern WC2, a first string separation structure SC1, a second string separation structure SC2, etc.

The first substrate 100 and the second substrate 200 may include a cell array region CAR, a selection string region SSR, a through region THR, and an extension region EXT.

A memory cell array including a plurality of memory cells may be formed on the cell array region CAR. The extension region EXT may be disposed around the cell array region CAR. For example, the extension region EXT may surround or extend around the cell array region CAR. The selection string region SSR and the through region THR may be disposed between the cell array region CAR and the extension region EXT. A configuration disposed in the cell array region CAR will be described below, and a configuration disposed in the selection string region SSR, the through region THR, and the extension region EXT will be described.

For example, the first substrate 100 may include a semiconductor substrate such as a silicon substrate, a germanium substrate, a silicon-germanium substrate, etc. In some embodiments, the first substrate 100 may include a silicon-on-insulator (SOI) substrate, a germanium-on-insulator (GOI) substrate, etc. In some embodiments, the first substrate 100 may include polysilicon (poly Si).

The first substrate 100 may include a first surface 100_A, and a second surface 100_B opposite to the first surface 100_A. The second surface 100_B of the first substrate 100 may be a surface on which the first mold structure MS1 and the first channel structure CH1 are disposed. The first surface 100_A of the first substrate 100 may be referred to as a back side of the first substrate 100. The second surface 100_B of the first substrate 100 may be referred to as a front side of the first substrate 100.

The first insulating substrate 101 may be provided on the selection string region SSR, the through region THR, and the extension region EXT. The first insulating substrate 101 may be disposed on the first substrate 100. However, embodiments are not limited thereto. Unlike the illustration, the first substrate 100 may not be disposed on the selection string region SSR, the through region THR, and the extension region EXT, but only the first insulating substrate 101 may be disposed thereon.

For example, the first insulating substrate 101 may include at least one of silicon oxide, silicon nitride, silicon oxynitride, and/or silicon carbide, but embodiments are not limited thereto.

In the cell array region CAR, the first mold structure MS1 may be disposed on the first substrate 100. The first mold structure MS1 may be formed on the second surface 100_B of the first substrate 100. The first mold structure MS1 may include a plurality of first mold insulating layers 110, a plurality of first gate electrodes 120, and a plurality of first string gate electrodes 130, which may be alternately stacked in a third direction D3. Each of the first mold insulating layers 110, the first gate electrodes 120, and the first string gate electrodes 130 may have a layered structure extending parallel to the second surface 100_B of the first substrate 100. Specifically, the plurality of first mold insulating layers 110 and the plurality of first gate electrodes 120 may be alternately stacked on the second surface 100_B of the first substrate 100. The plurality of first mold insulating layers 110 and the plurality of first string gate electrodes 130 may be alternately stacked on the plurality of first gate electrodes 120. The first gate electrodes 120 and the first string gate electrodes 130 may be disposed to be spaced apart in the third direction D3.

In some embodiments, some of the plurality of first gate electrodes 120 may be used as a ground select line GSL and an erase control line ECL of the semiconductor memory device. For example, among the plurality of first gate electrodes 120, the first gate electrodes 120 adjacent to first source structures 102 and 104 may be used as the erase control line ECL. The erase control line ECL may be used as a gate electrode of an erase transistor. The erase transistor may generate a Gate Induced Drain Leakage (GIDL) to perform an erase operation on a plurality of memory cell transistors. The first gate electrode 120 adjacent to the erase control line ECL may be provided as the ground select line GSL. However, embodiments are not limited thereto. The arrangement and number of the ground select lines GSL may vary. In some embodiments, the first string gate electrodes 130 may be provided as a string select line SSL of the semiconductor memory device.

The first gate electrodes 120 and the first string gate electrodes 130 may each include a conductive material, for example, a metal such as tungsten (W), cobalt (Co), nickel (Ni), or a semiconductor material such as silicon, but embodiments are not limited thereto.

The first mold insulating layer 110 may include an insulating material. For example, the first mold insulating layer 110 may include at least one of silicon oxide, silicon nitride, and/or silicon oxynitride, but embodiments are not limited thereto.

The first channel structure CH1 may be disposed on the cell array region CAR. The first channel structure CH1 may be formed through the first mold structure MS1. For example, the first channel structure CH1 may be formed through and intersect each of the plurality of first mold insulating layers 110, the plurality of first gate electrodes 120, and the plurality of first string gate electrodes 130. The first channel structure CH1 may be disposed in a first channel hole extending in the third direction D3. The first channel structure CH1 may have a pillar shape (e.g., a cylindrical shape) extending in the third direction D3. In some embodiments, the first channel structure CH1 may have an inclined side surface in a cross-sectional view that progressively narrows in width (e.g. length in the second direction D2) toward the first substrate 100. However, embodiments are not limited thereto.

The first channel structure CH1 may include an information storage film 140, a semiconductor pattern 148, and a filling pattern 149.

The semiconductor pattern 148 may extend in the third direction D3 through the first mold structure MS1. Although it is illustrated that the semiconductor pattern 148 has a cup shape, embodiments are not limited thereto. For example, the semiconductor pattern 148 may have various shapes such as a cylindrical shape, a rectangular cylindrical shape, a filled pillar shape, etc. For example, the semiconductor pattern 148 may include a semiconductor material such as a single crystal silicon, a polycrystalline silicon, an organic semiconductor material, a carbon nanostructure, etc., but embodiments are not limited thereto.

The information storage film 140 may be interposed between the semiconductor pattern 148 and each of the first gate electrodes 120 and between the semiconductor pattern 148 and each of the first string gate electrodes 130. For example, the information storage film 140 may extend along an outer surface of the semiconductor pattern 148. For example, the information storage film 140 may include at least one of silicon oxide, silicon nitride, silicon oxynitride, and/or a high-k material having a higher dielectric constant than silicon oxide. For example, the high-k material may include at least one of aluminum oxide, hafnium oxide, lanthanum oxide, tantalum oxide, titanium oxide, lanthanum hafnium oxide, lanthanum aluminum oxide, dysprosium scandium oxide, and/or a combination thereof.

In some embodiments, the first channel structures CH1 may be arranged in a zigzag fashion. For example, as illustrated in FIGS. 1 and 2, the first channel structures CH1 may be arranged to alternate with each other in a first direction D1 and a second direction D2. The first channel structures CH1 arranged in the zigzag fashion may further improve the integration density of the semiconductor memory device. In some embodiments, the first channel structures CH1 may be arranged in a honeycomb fashion.

In some embodiments, the information storage film 140 may include multiple films. The information storage film 140 may include a tunnel insulating film 142, a charge storage film 144, and a blocking insulating film 146, which may be sequentially stacked on the outer surface of the semiconductor pattern 148.

For example, the tunnel insulating film 142 may include the silicon oxide or a high-k material (e.g., aluminum oxide (Al₂O₃), hafnium oxide (HfO₂)) having a higher dielectric constant than the silicon oxide. For example, the charge storage film 144 may include silicon nitride. For example, the blocking insulating film 146 may include the silicon oxide or a high-k material (e.g., aluminum oxide (Al₂O₃) or hafnium oxide (HfO₂)) having a higher dielectric constant than the silicon oxide.

In some embodiments, the first channel structure CH1 may further include the filling pattern 149. The filling pattern 149 may be formed to fill the interior of the semiconductor pattern 148 in the cup shape. For example, the filling pattern 149 may include an insulating material such as silicon oxide, but embodiments are not limited thereto.

A first channel pad 182 may be disposed on the first channel structure CH1. The first channel pad 182 may be disposed on the first channel structure CH1 and electrically connected to the semiconductor pattern 148. The first channel contact 185 may be disposed on the first channel pad 182. For example, the first channel pad 182 may include polysilicon doped with impurities, but embodiments are not limited thereto.

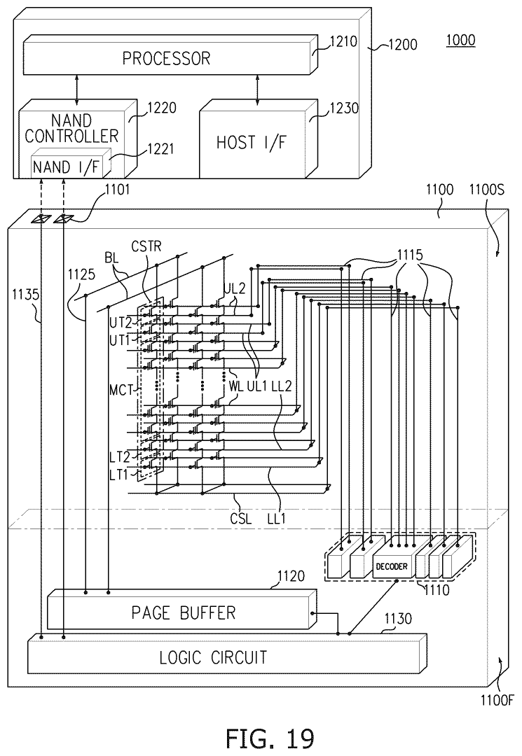

In some embodiments, the first source structures 102 and 104 may be formed on the first substrate 100. The first source structures 102 and 104 may be disposed between the first substrate 100 and the first mold structure MS1. For example, the first source structures 102 and 104 may extend along the second surface 100_B of the first substrate 100. The first source structures 102 and 104 may be formed to be connected to the semiconductor pattern 148 and/or the information storage film 140 of the first channel structure CH1. The first source structures 102 and 104 may be used as a common source line (e.g., CSL in FIG. 19) of the semiconductor memory device. For example, the first source structures 102 and 104 may include polysilicon or metal doped with an impurity, but is not limited thereto.

In some embodiments, the first channel structure CH1 may be formed through the first source structures 102 and 104. For example, a lower portion of the first channel structure CH1 may be formed through the first source structures 102 and 104 and be disposed in the first substrate 100.

In some embodiments, the first source structures 102 and 104 may include multiple films. For example, the first source structures 102 and 104 may include a first source layer 102 and a second source layer 104 sequentially stacked on the first substrate 100. Each of the first source layer 102 and the second source layer 104 may include polysilicon doped with an impurity or polysilicon undoped with an impurity, but embodiments are not limited thereto. The first source layer 102 may be in contact with the semiconductor pattern 148 and provided as a common source line (e.g., CSL of FIG. 19) of the semiconductor memory device. The second source layer 104 may be used as a support layer for preventing the mold stack from collapsing or falling in a replacement process for forming the first source layer 102.

Although not illustrated, a base insulating film may be interposed between the first substrate 100 and the first source structures 102 and 104. For example, the base insulating film may include at least one of silicon oxide, silicon nitride, and silicon oxynitride, but is not limited thereto.

In some embodiments, the first source structures 102 and 104 may not be formed in the selection string region SSR, the through region THR, and the extension region EXT where the first insulating substrate 101 is disposed.

The first block separation pattern WC1 may extend in the first direction D1 to cut or divide the first mold structure MS1. An area between the first block separation patterns WC1 adjacent to each other in the second direction D2 may be defined as a cell block of the semiconductor memory device.

The first string separation structure SC1 may be disposed between the first block separation patterns WC1 adjacent to each other. The first string separation structure SC1 may extend in the first direction D1 to cut the first string gate electrode 130. For example, the first string separation structure SC1 formed in the cell block may cut the first string gate electrode 130, and the divided first string gate electrodes 130 may independently control each region.

The first block separation pattern WC1 and the first string separation structure SC1 may include an insulating material, for example, at least one of silicon oxide, silicon nitride, and/or silicon oxynitride, but are not limited thereto.

The first bit line 192 may be formed on the first interlayer insulating film 180. The first bit line 192 may extend in the second direction D2 to intersect the first block separation pattern WC1. In addition, the first bit line 192 may extend in the second direction D2 and be connected to a plurality of first channel structures CH1 arranged along the second direction D2. For example, a first channel contact 185 connected to an upper portion of each of the first channel structures CH1 may be formed in the first interlayer insulating film 180. The first bit line 192 may be electrically connected to the first channel structures CH1 through the first channel contact 185.

The first wiring insulating film 190 may be disposed on the first interlayer insulating film 180. The first wiring structure 194 may be disposed in the first wiring insulating film 190. The first wiring structure 194 may be connected to the first bit line 192 and the first bonding pad 195.

The first bonding pad 195 may be disposed on the first wiring insulating film 190. The first bonding pad 195 may be disposed on an upper portion of the first wiring insulating film 190. The first wiring insulating film 190 may surround or extend around a portion of the first bonding pad 195. The first wiring insulating film 190 may expose an upper surface of the first bonding pad 195. In some embodiments, the upper surface of the first wiring insulating film 190 may be disposed on the same plane as the upper surface of the first bonding pad 195.

The second substrate 200 may be disposed on the first wiring insulating film 190. The second bonding pad 295 may be disposed below the second substrate 200. The second substrate 200 may surround or extend around a portion of the second bonding pad 295. The second substrate 200 may expose a lower surface of the second bonding pad 295. In some embodiments, a third surface 200_A of the second substrate 200 and the lower surface of the second bonding pad 295 may be disposed on the same plane.

The first bonding pad 195 and the second bonding pad 295 may be disposed between the first wiring insulating film 190 and the second substrate 200. The second bonding pad 295 may be disposed on the first bonding pad 195. The first bonding pad 195 and the second bonding pad 295 may be in contact with each other. The first bonding pad 195 and the second bonding pad 295 may be bonded to each other.

In some embodiments, the second substrate 200 may be an insulating substrate. For example, the second substrate 200 may include at least one of silicon oxide, silicon nitride, silicon oxynitride, and/or silicon carbide, but embodiments are not limited thereto. The second substrate 200 may include the third surface 200_A and a fourth surface 200_B opposite to the third surface 200_A. The third surface 200_A of the second substrate 200 may be opposite to the second surface 100_B of the first substrate 100. The third surface 200_A of the second substrate 200 may be referred to as a back side of the second substrate 200. The fourth surface 200_B of the second substrate 200 may be referred to as a front side of the second substrate 200.

In the cell array region CAR, the second mold structure MS2 may be disposed on the second substrate 200. The second mold structure MS2 may be formed on the fourth surface 200_B of the second substrate 200. The second mold structure MS2 may include a plurality of second mold insulating layers 210, a plurality of second gate electrodes 220, and a plurality of second string gate electrodes 230, which are alternately stacked in the third direction D3. Each of the second mold insulating layers 210, the second gate electrodes 220, and the second string gate electrodes 230 may have a layered structure extending parallel to the fourth surface 200_B of the second substrate 200. Specifically, the plurality of second mold insulating layers 210 and the plurality of second gate electrodes 220 may be alternately stacked on the fourth surface 200_B of the second substrate 200. The plurality of second mold insulating layers 210 and the plurality of second string gate electrodes 230 may be alternately stacked on the plurality of second gate electrodes 220. The second gate electrodes 220 and the second string gate electrodes 230 may be disposed to be spaced apart in the third direction D3.

In some embodiments, some of the plurality of second gate electrodes 220 may be used as the ground select line GSL and the erase control line ECL of the semiconductor memory device. For example, among the plurality of second gate electrodes 220, the second gate electrodes 220 adjacent to second source structures 202 and 204 may be used as the erase control line ECL. The erase control line ECL may be used as a gate electrode of an erase transistor. The erase transistor may generate Gate Induced Drain Leakage (GIDL) to perform an erase operation on a plurality of memory cell transistors. The second gate electrode 220 adjacent to the erase control line ECL may be provided as the ground select line GSL. However, embodiments are not limited thereto. The arrangement and number of the ground select lines GSL may vary. In some embodiments, the second string gate electrodes 230 may be provided as a string select line SSL of the semiconductor memory device.

The second gate electrodes 220 and the second string gate electrodes 230 may each include a conductive material, for example, a metal such as tungsten (W), cobalt (Co), and/or nickel (Ni), or a semiconductor material such as silicon, but embodiments are not limited thereto.

The second mold insulating layer 210 may include an insulating material. For example, the second mold insulating layer 210 may include at least one of silicon oxide, silicon nitride, and/or silicon oxynitride, but embodiments are not limited thereto.

The second channel structure CH2 may be disposed on the cell array region CAR. The second channel structure CH2 may be formed through the second mold structure MS2. For example, the second channel structure CH2 may be formed through and intersect each of the plurality of second mold insulating layers 210, the plurality of second gate electrodes 220, and the plurality of second string gate electrodes 230. The second channel structure CH2 may be disposed in a second channel hole extending in the third direction D3. The second channel structure CH2 may have a pillar shape (e.g., a cylindrical shape) extending in the third direction D3. In some embodiments, the second channel structure CH2 may have an inclined side surface in a cross-sectional view that progressively narrows in width (e.g. length in the second direction D2) toward the second substrate 200. However, embodiments are not limited thereto.

The second channel structure CH2 may include an information storage film, a semiconductor pattern, and a filling pattern. The description of the information storage film, the semiconductor pattern, and the filling pattern of the second channel structure CH2 may be similar to the description of the information storage film 140, the semiconductor pattern 148, and the filling pattern 149 of the first channel structure CH1.

A second channel pad 282 may be disposed on the second channel structure CH2. The second channel pad 282 may be disposed above the second channel structure CH2 and electrically connected to the semiconductor pattern of the second channel structure CH2. The second channel contact 285 may be disposed on the second channel pad 282. For example, the second channel pad 282 may include polysilicon doped with impurities, but embodiments are not limited thereto.

In some embodiments, the second source structures 202 and 204 may be formed on the second substrate 200. The second source structures 202 and 204 may be disposed between the second substrate 200 and the second mold structure MS2. For example, the second source structures 202 and 204 may extend along the fourth surface 200_B of the second substrate 200. The second source structures 202 and 204 may be formed to be connected to the semiconductor pattern and/or the information storage film of the second channel structure CH2. The second source structures 202 and 204 may be used as a common source line (e.g., CSL in FIG. 19) of the semiconductor memory device. For example, the second source structures 202 and 204 may include polysilicon or metal doped with impurities, but embodiments are not limited thereto.

In some embodiments, the second channel structure CH2 may be formed through the second source structures 202 and 204. For example, a lower portion of the second channel structure CH2 may be formed through the second source structures 202 and 204 and disposed in the second substrate 200.

In some embodiments, the second source structures 202 and 204 may include multiple films. For example, the second source structures 202 and 204 may include a third source layer 202 and a fourth source layer 204 sequentially stacked on the second substrate 200. Each of the third source layer 202 and the fourth source layer 204 may include polysilicon doped with an impurity or polysilicon undoped with an impurity, but embodiments are not limited thereto. The third source layer 202 may be in contact with the semiconductor pattern of the second channel structure CH2 and may be provided as a common source line (e.g., CSL of FIG. 19) of the semiconductor memory device. The fourth source layer 204 may be used as a support layer for preventing the mold stack from collapsing or falling down in a replacement process for forming the third source layer 202.

Although not illustrated, a base insulating film may be interposed between the second substrate 200 and the second source structures 202 and 204. For example, the base insulating film may include at least one of silicon oxide, silicon nitride, and/or silicon oxynitride, but is not limited thereto.

In some embodiments, the second source structures 202 and 204 may not be formed in the selection string region SSR, the through region THR, and the extension region EXT where a second insulating substrate 201 is disposed.

The second block separation pattern WC2 may extend in the first direction D1 to cut or divide the second mold structure MS2. An area between the second block separation patterns WC2 adjacent to each other in the second direction D2 may be defined as a cell block of the semiconductor memory device. From a plan view, the second block separation pattern WC2 is illustrated as a rectangle extending in the first direction D1, but the embodiments are not limited thereto. For example, the long side of the second block separation pattern WC2 may be formed with a plurality of curves.

The second string separation structure SC2 may be disposed between the second block separation patterns WC2 adjacent to each other. The second string separation structure SC2 may extend in the first direction D1 to cut the second string gate electrode 230. For example, the second string separation structure SC2 formed in the cell block may cut the second string gate electrode 230, and the divided second string gate electrodes 230 may independently control each region.

The second block separation pattern WC2 and the second string separation structure SC2 may include an insulating material, for example, at least one of silicon oxide, silicon nitride, and silicon oxynitride, but are not limited thereto.

The second bit line 292 may be formed on the second interlayer insulating film 280. The second bit line 292 may extend in the second direction D2 to intersect the second block separation pattern WC2. In addition, the second bit line 292 may extend in the second direction D2 and be connected to a plurality of second channel structures CH2 arranged along the second direction D2. For example, a second channel contact 285 connected to an upper portion of each of the second channel structures CH2 may be formed in the second interlayer insulating film 280. The second bit line 292 may be electrically connected to the second channel structures CH2 through the second channel contact 285.

The second wiring insulating film 290 may be disposed on the second interlayer insulating film 280. The second wiring structure 294 may be disposed in the second wiring insulating film 290. The second wiring structure 294 may be connected to the second bit line 292.

Configurations disposed on the selection string region SSR, the through region THR, and the extension region EXT will be described with reference to FIGS. 4 to 7.

The first string gate electrodes 130 may extend in the first direction D1 and be disposed on the selection string region SSR. For example, one end of the first string gate electrodes 130 may extend to the selection string region SSR. The one end of the plurality of first string gate electrodes 130 may be stacked in a staircase shape on the selection string region SSR. The closer the plurality of first string gate electrodes 130 are to the first substrate 100, the closer the one end of the plurality of first string gate electrodes 130 may extend towards the through region THR. The plurality of first string gate electrodes 130 may be arranged in a staircase shape, and may include a first pad portion 131 on which the first string gate contact 150 is disposed. The first pad portion 131 may be covered by, or overlapped by, or on the first interlayer insulating film 180. The number of the first string gate electrodes 130 is illustrated as four, but embodiments are not limited thereto.

The first string gate contact 150 may be formed through the first interlayer insulating film 180 and connected to each of the plurality of first string gate electrodes 130. The first string gate contact 150 may be disposed on the first pad portion 131 of the first string gate electrode 130. The first string gate contact 150 may be electrically connected to the first string gate electrode 130.

In some embodiments, the first mold structure MS1 may further include a plurality of first dummy string electrodes 132. The plurality of first dummy string electrodes 132 may be stacked on the plurality of first gate electrodes 120 on the selection string region SSR. The plurality of first dummy string electrodes 132 may be alternately stacked with the plurality of first mold insulating layers 110 on the plurality of first gate electrodes 120. The plurality of first dummy string electrodes 132 may be disposed at the same level as the plurality of first string gate electrodes 130. For example, the first dummy string electrodes 132 may overlap with the first string gate electrodes 130 in the first direction D1. The plurality of first dummy string electrodes 132 may be spaced apart from the plurality of first string gate electrodes 130 in the first direction D1. A portion of the first gate electrodes 120 may be exposed between the plurality of first dummy string electrodes 132 and the plurality of first string gate electrodes 130.

One end of the plurality of first dummy string electrodes 132 may be stacked in a staircase shape. The closer the plurality of first dummy string electrodes 132 are to the first substrate 100, the farther the one end of the plurality of first dummy string electrodes 132 may extend away from the through region THR. The plurality of first dummy string electrodes 132 may include first dummy pad portions 133 arranged in a staircase shape. The first dummy pad portions 133 may be covered by, or overlapped by, or on the first interlayer insulating film 180. The staircase shape of the plurality of first dummy string electrodes 132 and the staircase shape of the plurality of first string gate electrodes 130 may be opposite to each other in the first direction D1.

The first interlayer insulating film 180 may cover, or overlap, or be on the first mold structure MS1. The first interlayer insulating film 180 may cover, or overlap, or be on the first string gate electrodes 130 and the first dummy string electrodes 132. The first interlayer insulating film 180 may surround or extend around the first string gate contacts 150.

The first wiring insulating film 190 may be disposed on the first interlayer insulating film 180. A first string wiring 157 may be disposed on the first string gate contact 150. The first string wiring 157 and the first wiring structure 194 may be disposed in the first wiring insulating film 190. The first wiring structure 194 may be connected to the first string wiring 157. The first wiring structure 194 may be connected to the first bonding pad 195 to be described below. The first string wiring 157 and the first bonding pad 195 may be electrically connected to each other by the first wiring structure 194.

The second string gate electrodes 230 may extend in the first direction D1 and disposed on the selection string region SSR. For example, one end of the second string gate electrodes 230 may extend to the selection string region SSR. The one end of the plurality of second string gate electrodes 230 may be stacked in a staircase shape on the selection string region SSR. The closer the plurality of second string gate electrodes 230 are to the second substrate 200, the closer the one end of the plurality of second string gate electrodes 230 may extend towards the through region THR. The plurality of second string gate electrodes 230 may be arranged in a staircase shape, and may include a second pad portion 231 on which the second string gate contact 250 is disposed. The second pad portion 231 may be covered by, or overlapped by, or be on the second interlayer insulating film 280. The number of the second string gate electrodes 230 is illustrated as four, but embodiments are not limited thereto.

The second string gate contact 250 may be formed through the second interlayer insulating film 280 and may be connected to each of the plurality of second string gate electrodes 230. The second string gate contact 250 may be disposed on the second pad portion 231 of the second string gate electrode 230. The second string gate contact 250 may be electrically connected to the second string gate electrode 230.

In some embodiments, the second mold structure MS2 may further include a plurality of second dummy string electrodes 232. The plurality of second dummy string electrodes 232 may be stacked on the plurality of second gate electrodes 220 on the selection string region SSR. The plurality of second dummy string electrodes 232 may be alternately stacked with the plurality of second mold insulating layers 210 on the plurality of second gate electrodes 220. The plurality of second dummy string electrodes 232 may be disposed at the same level as the plurality of second string gate electrodes 230. For example, the second dummy string electrodes 232 may overlap with the second string gate electrodes 230 in the first direction D1. The plurality of second dummy string electrodes 232 may be spaced apart from the plurality of second string gate electrodes 230 in the first direction D1. A portion of the second gate electrodes 220 may be exposed between the plurality of second dummy string electrodes 232 and the plurality of second string gate electrodes 230.

One end of the plurality of second dummy string electrodes 232 may be stacked in a staircase shape. The closer the plurality of second dummy string electrodes 232 are to the second substrate 200, the farther the one end of the plurality of second dummy string electrodes 232 may extend away from the through region THR. The plurality of second dummy string electrodes 232 may include second dummy pad portions 233 arranged in a staircase shape. The second dummy pad portions 233 may be covered by, or overlapped by, or on the second interlayer insulating film 280. The staircase shape of the plurality of second dummy string electrodes 232 and the staircase shape of the plurality of second string gate electrodes 230 may be opposite to each other in the first direction D1.

The second interlayer insulating film 280 may cover, or overlap, or be on the second mold structure MS2. The second interlayer insulating film 280 may cover, or overlap, or be on the second string gate electrodes 230 and the second dummy string electrodes 232. The second interlayer insulating film 280 may surround or extend around the second string gate contacts 250.

The second wiring insulating film 290 may be disposed on the second interlayer insulating film 280. A second string wiring 257 may be disposed on the second string gate contact 250. The second string wiring 257 and the second wiring structure 294 may be disposed in the second wiring insulating film 290. The second wiring structure 294 may be connected to the second string wiring 257. The second wiring structure 294 may be connected to the second bonding pad 295 to be described below. The second string wiring 257 and the second bonding pad 295 may be electrically connected to each other by the second wiring structure 294.

The first through via 260 may be disposed on the through region THR. The through region THR may be disposed at one side of the selection string region SSR. The first through via 260 may extend in the third direction D3. The first through via 260 may be formed through the second mold structure MS2, the second insulating substrate 201, and the fourth surface 200_B of the second substrate 200. For example, the first through via 260 may be formed through the plurality of second mold insulating layers 210, the plurality of second gate electrodes 220, and the plurality of second dummy string electrodes 232 of the second mold structure MS2. The first through via 260 may be spaced apart from the second dummy pad portion 233 of the second dummy string electrode 232 in the first direction D1.

In some embodiments, the diameter (e.g. a length in the first direction D1) of the first through via 260 may not be constant. For example, the diameter of the first through via 260 may increase as a distance from the second substrate 200 increases. In some embodiments, the diameter of the first through via 260 may be equal to or greater than the diameter of the first channel structure CH1 and the diameter of the second channel structure CH2.

One end of the first through via 260 may be connected to the second wiring structure 294. The one end of the first through via 260 may be electrically connected to the second string gate electrode 230 through the second wiring structure 294 and the second string gate contact 250.

The other end of the first through via 260 may be connected to the second bonding pad 295. The other end of the first through via 260 may be electrically connected to the first string gate electrode 130 through the second bonding pad 295, the first bonding pad 195, the first wiring structure 194, and the first string gate contact 150. The first through via 260 may be electrically connected to the first string gate electrode 130 and the second string gate electrode 230. As a result, electrical characteristics and integration density of the semiconductor memory device may be improved.

The first word line contact 175 may be disposed on the extension region EXT. The first word line contact 175 may extend in the third direction D3 and be formed through at least a portion of the first mold structure MS1. The first word line contact 175 may be connected to one of the plurality of first gate electrodes 120. The first word line contact 175 may be formed through a portion of the first mold structure MS1 disposed above the connected first gate electrode 120. For example, the first word line contact 175 may be formed through some of the plurality of first dummy string electrodes 132 and the plurality of first gate electrodes 120.

A first contact via 178 may be disposed on the first word line contact 175. The first contact via 178 may be electrically connected to the first bonding pad 195 through the first wiring structure 194.

The second word line contact 275 may be disposed on the extension region EXT. The second word line contact 275 may extend in the third direction D3 and be formed through at least a portion of the second mold structure MS2. The second word line contact 275 may be connected to one of the plurality of second gate electrodes 220. The second word line contact 275 may be formed through a portion of the second mold structure MS2 disposed above the connected second gate electrodes 220. For example, the second word line contact 275 may be formed through some of the plurality of second dummy string electrodes 232 and the plurality of second gate electrodes 220. The first word line contact 175 and the second word line contact 275 may electrically connect one of the plurality of first gate electrodes 120 and second gate electrodes 220 respectively to a word line (not shown).

A second contact via 278 may be disposed on the second word line contact 275. The second contact via 278 may be electrically connected to the second through via 270 through the second wiring structure 294.

The second through via 270 may be disposed on the extension region EXT. The second through via 270 may be disposed adjacent to the second word line contact 275. As illustrated in FIG. 1, from a plan view, the second through via 270 may be disposed between the second word line contacts 275.

The second through via 270 may be connected to the first word line contact 175 and the second word line contact 275. For example, one end of the second through via 270 may be connected to the second word line contact 275 through the second wiring structure 294, and the other end of the second through via 270 may be connected to the first word line contact 175 through the second bonding pad 295, the first bonding pad 195, and the first wiring structure 194.

In some embodiments, the diameter of the second through via 270 may be the same as the diameter of the first through via 260. However, embodiments are not limited thereto. For example, the diameter of the second through via 270 may be different from the diameter of the first through via 260. The diameter of the second word line contact 275 may be greater than the diameter of the second through via 270.

Each of the first through via 260 and the second through via 270 may include a barrier layer and a filling layer. The barrier layer may define the outer side of each of the first through via 260 and the second through via 270. The filling layer may fill the interior of the barrier layer. The barrier layer may include an insulating material, and the filling layer may include a conductive material. For example, the conductive material may include a metal such as aluminum (Al), tungsten (W), cobalt (Co), nickel (Ni), ruthenium (Ru), silver (Ag), gold (Au), manganese (Mn), molybdenum (Mo), or a semiconductor material such as silicon, but embodiments are not limited thereto.

The first word line contact 175 may include a first contact spacer 176 and a first contact filling layer 177. The first contact spacer 176 may define the outer side of the first word line contact 175. The first contact filling layer 177 may fill the interior of the first contact spacer 176. The second word line contact 275 may include a second contact spacer 276 and a second contact filling layer 277. The second contact spacer 276 may define the outer side of the second word line contact 275. The second contact filling layer 277 may fill the interior of the second contact spacer 276.

The first contact spacer 176 and the second contact spacer 276 may include an insulating material. For example, the first contact filling layer 177 and the second contact filling layer 277 may include at least one of aluminum (Al), tungsten (W), cobalt (Co), nickel (Ni), ruthenium (Ru), silver (Ag), gold (Au), manganese (Mn), and/or molybdenum (Mo).

In some embodiments, the second mold structure MS2 may further include a dummy channel structure DCH. As illustrated in FIG. 1, the dummy channel structure DCH may be disposed on the selection string region SSR.

Referring back to FIGS. 1 to 7, the peripheral circuit structure PERI may be disposed below the cell structure CELL. For example, the peripheral circuit structure PERI may be disposed on the first surface 100_A of the first substrate 100 of the cell structure CELL. The peripheral circuit structure PERI may include a peripheral circuit substrate 300, a peripheral circuit element 360, and a peripheral circuit wiring structure 380.

For example, the peripheral circuit substrate 300 may include a semiconductor substrate such as a silicon substrate, a germanium substrate, a silicon-germanium substrate, etc. In some embodiment, the peripheral circuit substrate 300 may include a silicon-on-insulator (SOI) substrate, a germanium-on-insulator (GOI) substrate, etc.

The peripheral circuit element 360 may be formed on the peripheral circuit substrate 300. The peripheral circuit element 360 may configure a peripheral circuit that controls the operation of the semiconductor memory device. For example, the peripheral circuit element 360 may include a logic circuit 1130, a page buffer 1120, a decoder circuit 1110, etc. of FIG. 19. In the following description, the surface of the peripheral circuit substrate 300 where the peripheral circuit element 360 is disposed may be referred to as a front side of the peripheral circuit substrate 300. Conversely, the surface of the peripheral circuit substrate 300 opposite to the front side of the peripheral circuit substrate 300 may be referred to as a back side of the peripheral circuit substrate 300.

For example, the peripheral circuit element 360 may include a transistor, but embodiments are not limited thereto. For example, the peripheral circuit element 360 may include not only various active elements such as transistors, etc., but also various passive elements such as capacitors, registers, inductors, etc.

The peripheral circuit wiring structure 380 may be formed on the peripheral circuit element 360. For example, a peripheral circuit insulating film 340 may be formed on the front side of the peripheral circuit substrate 300, and the peripheral circuit wiring structure 380 may be formed in the peripheral circuit insulating film 340. The peripheral circuit wiring structure 380 may be electrically connected to the peripheral circuit element 360. The number, arrangement, etc. of the layers of the peripheral circuit wiring structure 380 illustrated herein are merely examples, and the embodiments are not limited thereto.

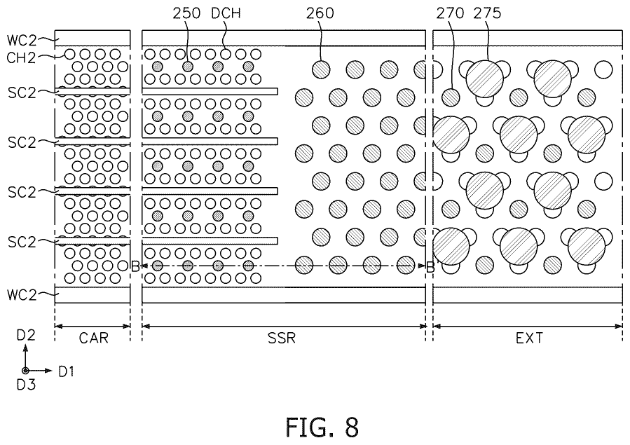

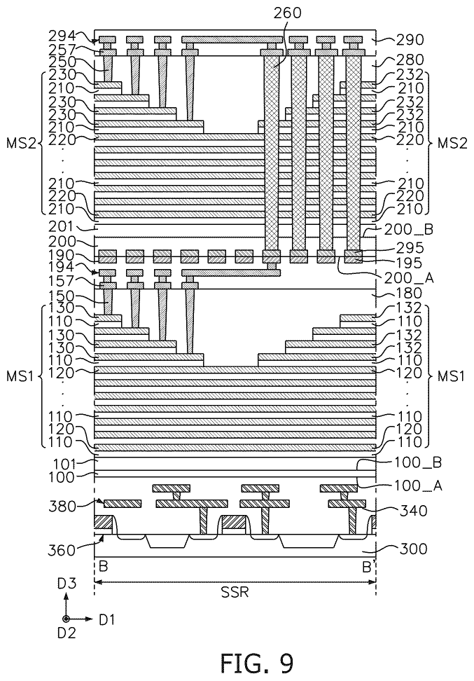

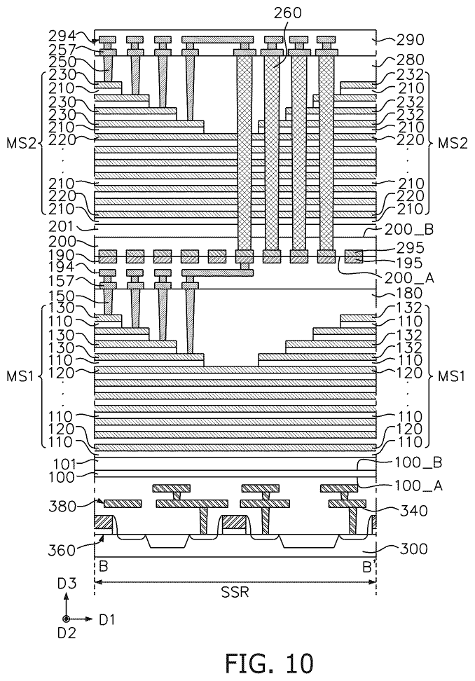

FIG. 8 is an example plan view provided to explain a semiconductor memory device according to some embodiments. FIG. 9 is a cross-sectional view taken along line B-B of FIG. 8 according to some embodiments. FIG. 10 is a cross-sectional view taken along the line B-B of FIG. 8 according to some embodiments. For convenience of description, different configurations from those described in FIGS. 1 to 7 will be mainly described.

Referring to FIGS. 8 to 10, in a semiconductor memory device according to some embodiments, the first through via 260 may be disposed on the selection string region SSR.

In some embodiments, the second mold structure MS2 may further include the plurality of second dummy string electrodes 232. The plurality of second dummy string electrodes 232 may be stacked on the plurality of second gate electrodes 220 on the selection string region SSR. The plurality of second dummy string electrodes 232 may be alternately stacked with the plurality of second mold insulating layers 210 on the plurality of second gate electrodes 220. The plurality of second dummy string electrodes 232 may be disposed at the same level as the plurality of second string gate electrodes 230.

One end of the plurality of second dummy string electrodes 232 may be stacked in a staircase shape. The plurality of second dummy string electrodes 232 may be arranged in a staircase shape, including the second dummy pad portions 233 that are partially exposed. The staircase shape of the plurality of second dummy string electrodes 232 and the staircase shape of the plurality of second string gate electrodes 230 may be opposite to each other in the first direction D1.

The first through via 260 may be formed through the plurality of second dummy string electrodes 232 on the selection string region SSR. As illustrated in FIG. 9, the first through via 260 may extend in the third direction D3 through the second dummy pad portion 233 of the second dummy string electrode 232. As illustrated in FIG. 10, a portion of the first through via 260 may be formed through the second dummy pad portion 233 of the second dummy string electrode 232, and the remainder of the first through via 260 may be disposed between the second string gate electrodes 230 and the second dummy string electrode 232.

In the semiconductor memory device according to some embodiments, the first through via 260 may be formed on the second dummy string electrode 232 disposed on the selection string region SSR, thereby improving the integration density of the semiconductor memory device.

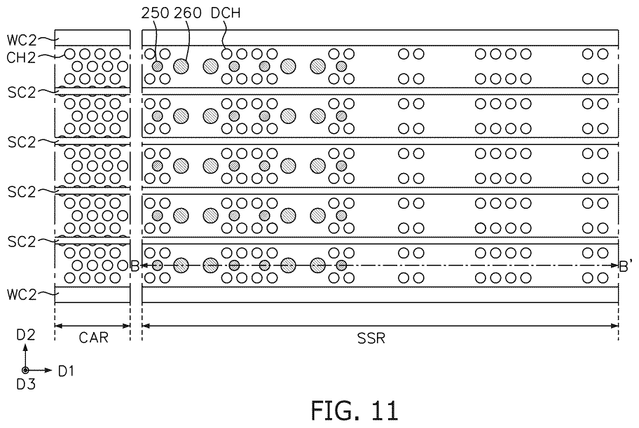

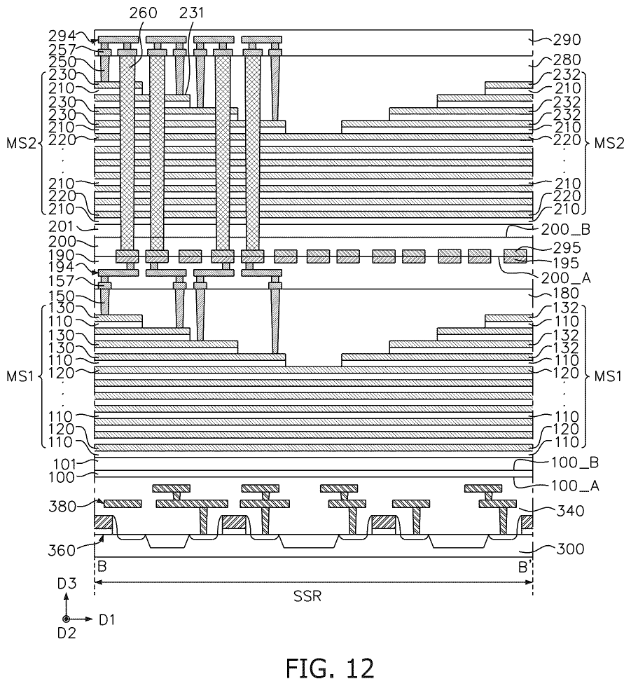

FIG. 11 is an example plan view provided to explain a semiconductor memory device according to some embodiments. FIG. 12 is a cross-sectional view taken along line B-B of FIG. 11. For convenience of description, different configurations from those described in FIGS. 1 to 7 will be mainly described.

Referring to FIGS. 11 and 12, in a semiconductor memory device according to some embodiments, the first through via 260 may be formed through the plurality of second string gate electrodes 230.

The second string gate electrodes 230 may extend in the first direction D1 and disposed on the selection string region SSR. For example, one end of the second string gate electrodes 230 may extend to the selection string region SSR. The one end of the plurality of second string gate electrodes 230 may be stacked in a staircase shape on the selection string region SSR. The plurality of second string gate electrodes 230 may be arranged in a staircase shape, including the second pad portions 231 that are partially exposed.

The first through via 260 may be formed through the plurality of second string gate electrodes 230 on the selection string region SSR. For example, the first through via 260 may extend in the third direction D3 through the second pad portion 231 of the second string gate electrodes 230. The first through via 260 may be disposed between two of a plurality of second string gate contacts 250.

The first through via 260 may be disposed adjacent to the second string gate contact 250. For example, the second string gate contact 250 may be disposed on at least one side of the first through via 260. In other words, one first through via 260 and one second string gate contact 250 may be disposed on one second pad portion 231. The length of the second wiring structure 294 connecting the first through via 260 and the adjacent second string gate contact 250 may be reduced. Because the first through via 260 and the second string gate contact 250 are disposed close to each other, the structure of the second wiring structure 294 connecting the first through via 260 and the second string gate contact 250 may be simplified. As a result, electrical characteristics and integration density of the semiconductor memory device may be improved.

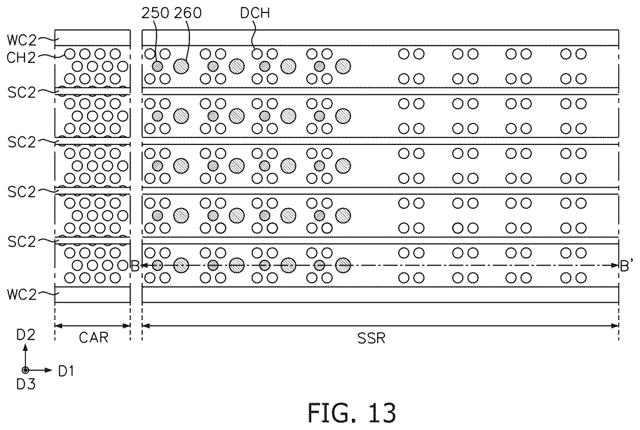

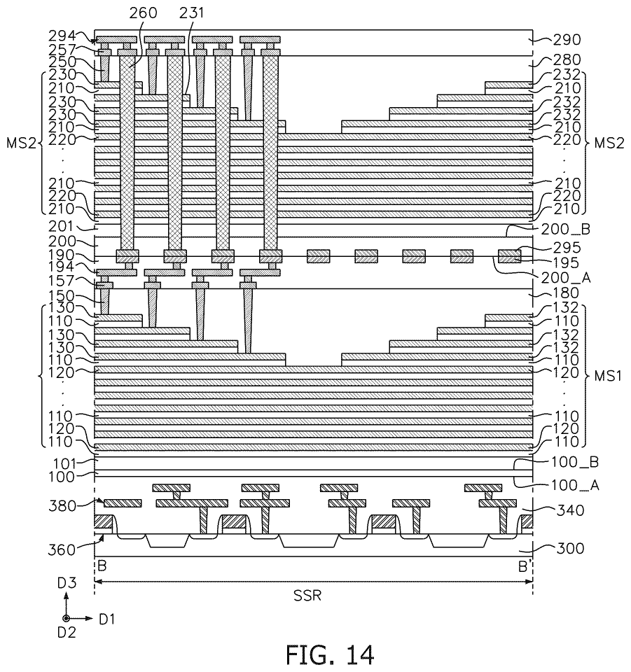

FIG. 13 is an example plan view provided to explain a semiconductor memory device according to some embodiments. FIG. 14 is a cross-sectional view taken along line B-B of FIG. 13. For convenience of description, different configurations from those described above with reference to FIGS. 1 to 7, 11 and 12 will be mainly described.

Referring to FIGS. 13 and 14, in a semiconductor memory device according to some embodiments, the first through via 260 may be formed through the plurality of second string gate electrodes 230.

The first through via 260 may be formed through the plurality of second string gate electrodes 230 on the selection string region SSR. For example, the first through via 260 may extend in the third direction D3 through the second pad portion 231 of the second string gate electrodes 230.

The second string gate contact 250 and the first through via 260 may be alternately disposed in the first direction D1. The first through via 260 may be disposed adjacent to the second string gate contact 250. For example, the second string gate contact 250 may be disposed on at least one side of the first through via 260. In other words, one first through via 260 and one second string gate contact 250 may be disposed on one second pad portion 231. The length of the second wiring structure 294 connecting the first through via 260 and the adjacent second string gate contact 250 may be reduced. Because the first through via 260 and the second string gate contact 250 are disposed close to each other, the structure of the second wiring structure 294 connecting the first through via 260 and the second string gate contact 250 may be simplified. As a result, electrical characteristics and integration density of the semiconductor memory device may be improved.

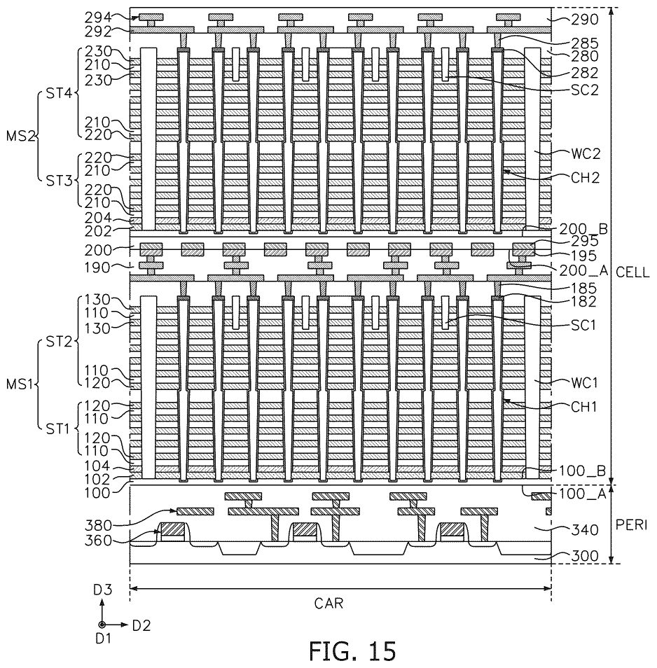

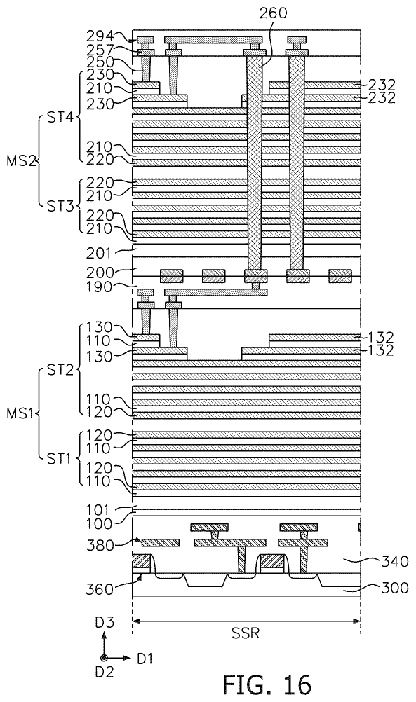

FIGS. 15 and 16 are diagrams provided to explain a semiconductor memory device according to some embodiments. For reference, FIG. 15 may correspond to a cross-sectional view of the cell array region CAR of the semiconductor memory device cut in the first direction D1, and FIG. 16 may correspond to a cross-sectional view of the selection string region SSR of the semiconductor memory device cut in the second direction D2. For convenience of description, different configurations from those described in FIGS. 1 to 7 will be mainly described.

Referring to FIGS. 15 and 16, in a semiconductor memory device according to some embodiments, the first mold structure MS1 and the second mold structure MS2 may include a plurality of stacks.

The first mold structure MS1 may include a first stack ST1 and a second stack ST2. The first stack ST1 may be disposed on the first substrate 100. The first stack ST1 may include the plurality of first mold insulating layers 110 and the plurality of first gate electrodes 120, which are alternately stacked in the third direction D3. The second stack ST2 may be disposed on the first stack ST1. The second stack ST2 may include the plurality of first mold insulating layers 110, the plurality of first gate electrodes 120, and the plurality of first string gate electrodes 130, which are alternately stacked in the third direction D3. The plurality of first string gate electrodes 130 may be stacked on the plurality of first gate electrodes 120 and spaced apart from each other.

A stack insulating film may be disposed between the first stack ST1 and the second stack ST2. In some embodiments, the thickness of the stack insulating film may be greater than the thickness of the first mold insulating layer 110. The thickness may refer to a thickness in the third direction D3.

The second mold structure MS2 may include a third stack ST3 and a fourth stack ST4. The third stack ST3 may be disposed on the second substrate 200. The third stack ST3 may include the plurality of second mold insulating layers 210 and the plurality of second gate electrodes 220, which are alternately stacked in the third direction D3. The fourth stack ST4 may be disposed on the third stack ST3. The fourth stack ST4 may include the plurality of second mold insulating layers 210, the plurality of second gate electrodes 220, and the plurality of second string gate electrodes 230, which are alternately stacked in the third direction D3. The plurality of second string gate electrodes 230 may be stacked on the plurality of second gate electrodes 220 and spaced apart from each other.

A stack insulating film may be disposed between the third stack ST3 and the fourth stack ST4. In some embodiments, the thickness of the stack insulating film may be greater than the thickness of the second mold insulating layer 210. The thickness may refer to a thickness in the third direction D3.

Although it is described that each of the first mold structure MS1 and the second mold structure MS2 includes two stacks, embodiments are not limited thereto. For example, each of the first mold structure MS1 and the second mold structure MS2 may include three or more stacks.

The first channel structure CH1 may extend in the third direction D3 through the first mold structure MS1. The first channel structure CH1 may have a step or a bent portion between the first stack ST1 and the second stack ST2. The second channel structure CH2 may extend in the third direction D3 through the second mold structure MS2. The second channel structure CH2 may have a step or a bent portion between the third stack ST3 and the fourth stack ST4.

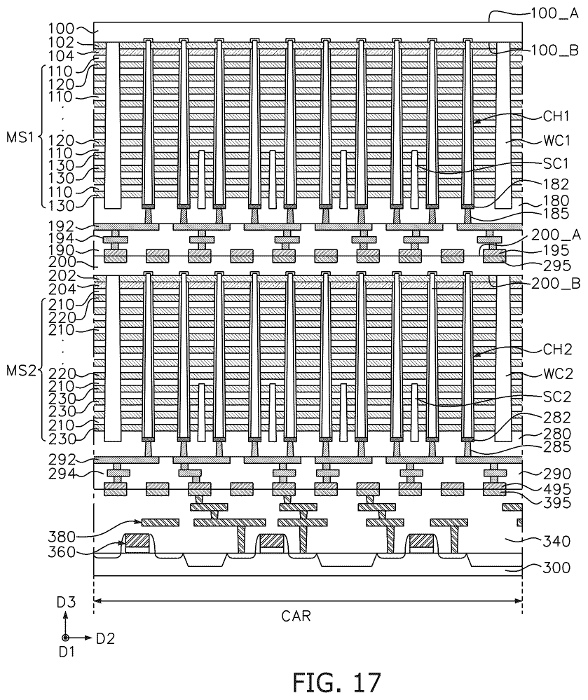

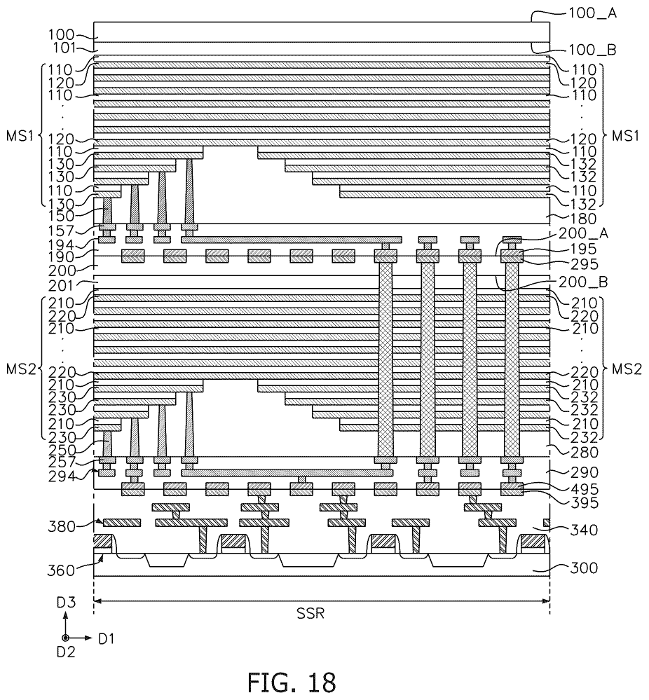

FIGS. 17 and 18 are diagrams provided to explain a semiconductor memory device according to some embodiments. For reference, FIG. 17 may correspond to a cross-sectional view of the cell array region CAR of the semiconductor memory device cut in the first direction D1, and FIG. 18 may correspond to a cross-sectional view of the selection string region SSR of the semiconductor memory device cut in the second direction D2. For convenience of description, different configurations from those described in FIGS. 1 to 7 will be mainly described.

Referring to FIGS. 17 and 18, the semiconductor memory device according to some embodiments may include a third bonding pad 395 and a fourth bonding pad 495 disposed between the peripheral circuit structure PERI and the cell structure CELL. The shape of the cell structure CELL of FIGS. 17 and 18 may be the same as the shape of the cell structure CELL described in FIGS. 1 to 7 rotated by 180 degrees.

The third bonding pad 395 may be disposed on an upper surface of the peripheral circuit insulating film 340. The peripheral circuit insulating film 340 may expose an upper surface of the third bonding pad 395. The upper surface of the peripheral circuit insulating film 340 may be opposite to the fourth surface 200_B of the second substrate 200.

The fourth bonding pad 495 may be disposed on the third bonding pad 395. The third bonding pad 395 and the fourth bonding pad 495 may be bonded to each other. The second wiring insulating film 290 may be disposed on the upper surface of the peripheral circuit insulating film 340. The third bonding pad 395 and the fourth bonding pad 495 may be disposed between the second wiring insulating film 290 and the peripheral circuit insulating film 340.

In some embodiments, the peripheral circuit structure PERI and the cell structure CELL may be formed on different wafers. For example, the cell structure CELL may be formed on a first wafer, and the peripheral circuit structure PERI may be formed on a second wafer. The semiconductor memory device may be manufactured by bonding the first wafer and the second wafer. For example, the fourth bonding pad 495 of the cell structure CELL and the third bonding pad 395 of the peripheral circuit structure PERI may be bonded to each other.

FIG. 19 is an example block diagram provided to explain an electronic system according to some embodiments.

Referring to FIG. 19, an electronic system 1000 may include the semiconductor memory device 1100 described with reference to FIGS. 1 to 18, and a controller 1200 electrically connected to the semiconductor memory device 1100. The electronic system 1000 may be a storage device including one or a plurality of semiconductor memory devices 1100 or an electronic device including the storage device. For example, the electronic system 1000 may be a solid state drive device (SSD), a universal serial bus (USB), a computing system, a medical device, or a communication device, which may include one or the plurality of semiconductor memory devices 1100.

For example, the semiconductor memory device 1100 may be the NAND flash memory device described above with reference to FIGS. 1 to 18. The semiconductor memory device 1100 may include a first structure 1100F and a second structure 1100S on the first structure 1100F. The first structure 1100F may be a peripheral circuit structure including the decoder circuit 1110, the page buffer 1120, and the logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may vary according to various embodiments.

In some embodiments, the upper transistors UT1 and UT2 may include a string select transistor, and the lower transistors LT1 and LT2 may include a ground select transistor. The gate lower lines LL1 and LL2 each may be gate electrodes of the lower transistors LT1 and LT2. The word lines WL may be gate electrodes of the memory cell transistors MCT, and the gate upper lines UL1 and UL2 may be gate electrodes of the upper transistors UT1 and UT2, respectively.

The common source line CSL, the first and second gate lower lines LL1 and LL2, the word lines WL, and the first and second gate upper lines UL1 and UL2 may be electrically connected to the decoder circuit 1110 through first connection lines 1115 extending from within the first structure 1100F to the second structure 1100S. The bit lines BL may be electrically connected to the page buffer 1120 through second connection wires 1125 extending from within the first structure 1100F to the second structure 1100S.

In the first structure 1100F, the decoder circuit 1110 and the page buffer 1120 may perform a control operation on at least one select memory cell transistor among the plurality of memory cell transistors MCT. The decoder circuit 1110 and the page buffer 1120 may be controlled by the logic circuit 1130. The semiconductor memory device 1100 may communicate with the controller 1200 through an input and output pad 1101 electrically connected to the logic circuit 1130. The input and output pad 1101 may be electrically connected to the logic circuit 1130 through an input and output connection wiring 1135 extending from within the first structure 1100F to the second structure 1100S.

The controller 1200 may include a processor 1210, a NAND controller 1220, and a host interface 1230. According to some embodiments, the electronic system 1000 may include the plurality of semiconductor memory devices 1100, and in this case, the controller 1200 may control the plurality of semiconductor memory devices 1100.

The processor 1210 may control the overall operation of the electronic system 1000 including the controller 1200. The processor 1210 may operate according to predetermined firmware, and may control the NAND controller 1220 to access the semiconductor memory device 1100. The NAND controller 1220 may include a NAND interface (or controller interface) 1221 that processes communication with the semiconductor memory device 1100. A control command for controlling the semiconductor memory device 1100, data to be written in the memory cell transistors MCT of the semiconductor memory device 1100, data to be read from the memory cell transistors MCT of the semiconductor memory device 1100, etc. may be transmitted through the NAND interface 1221. The host interface 1230 may provide a communication function between the electronic system 1000 and an external host. Upon receiving a control command from the external host through the host interface 1230, the processor 1210 may control the semiconductor memory device 1100 in response to the control command.

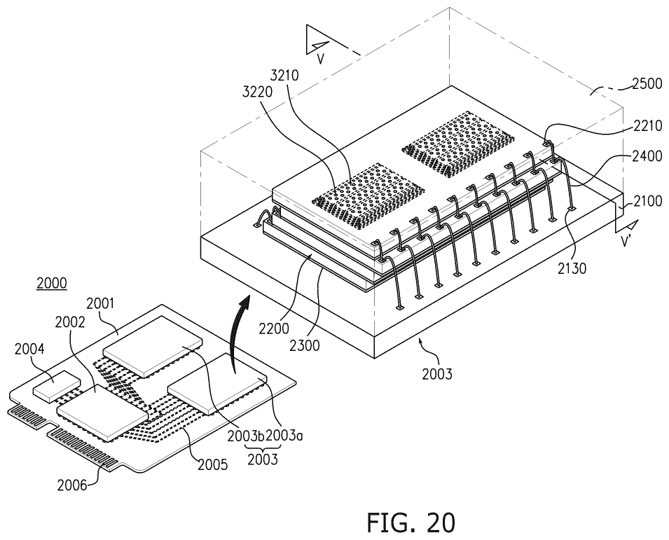

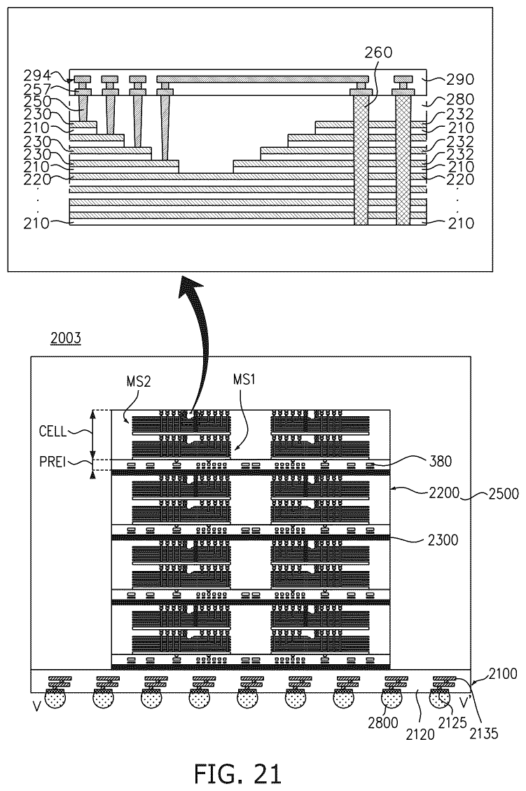

FIG. 20 is a perspective view provided as an example to explain an electronic system according to some embodiments. FIG. 21 is a schematic cross-sectional view taken along line V-V of FIG. 20.

Referring to FIGS. 20 and 21, an electronic system 2000 may include a main substrate 2001, a main controller 2002 mounted on the main substrate 2001, one or more semiconductor packages 2003, and a DRAM 2004. The semiconductor package 2003 and the DRAM 2004 may be connected to the main controller 2002 by wiring patterns 2005 formed on the main substrate 2001.

The main substrate 2001 may include a connector 2006 including a plurality of pins coupled to the external host. The number and arrangement of the plurality of pins in the connector 2006 may vary depending on a communication interface between the electronic system 2000 and the external host. In some embodiments, the electronic system 2000 may communicate with the external host according to any one of interfaces such as Universal Serial Bus (USB), Peripheral Component Interconnect Express (PCI-Express), Serial Advanced Technology Attachment (SATA), and M-Phy for Universal Flash Storage (UFS). In some embodiments, the electronic system 2000 may be operated by the power supplied from the external host through the connector 2006. The electronic system 2000 may further include a Power Management Integrated Circuit (PMIC) that distributes the power supplied from the external host to the main controller 2002 and the semiconductor package 2003.

The main controller 2002 may record data in the semiconductor package 2003 or read data from the semiconductor package 2003, and may improve the operation speed of the electronic system 2000.

The DRAM 2004 may be a buffer memory to alleviate the speed difference between the external host and the semiconductor package 2003 that is a data storage space. The DRAM 2004 included in the electronic system 2000 may also operate as a kind of cache memory, and may also provide a space for temporarily storing data in a control operation for the semiconductor package 2003. If the electronic system 2000 includes the DRAM 2004, in addition to the NAND controller for controlling the semiconductor package 2003, the main controller 2002 may further include a DRAM controller for controlling the DRAM 2004.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 disposed on a lower surface of each of the semiconductor chips 2200, a connection structure 2400 electrically connecting the semiconductor chips 2200 and the package substrate 2100, and a molding layer 2500 covering, or overlapping, or on the semiconductor chips 2200 and the connection structure 2400 on the package substrate 2100.

The package substrate 2100 may be a printed circuit board including package upper pads 2130. Each of the semiconductor chips 2200 may include an input and output pad 2210. The input and output pad 2210 may correspond to the input and output pad 1101 of FIG. 19. Each of the semiconductor chips 2200 may include metal lines 3210 and channel structures 3220. Each of the semiconductor chips 2200 may include the semiconductor memory device described above with reference to FIGS. 1 to 18.

In some embodiments, the connection structure 2400 may be a bonding wire electrically connecting the input and output pad 2210 to the package upper pads 2130. Therefore, in each of the first and second semiconductor packages 2003a and 2003b, the semiconductor chips 2200 may be electrically connected to each other with the bonding wire method, and may be electrically connected to the package upper pads 2130 of the package substrate 2100. In some embodiments, in each of the first and second semiconductor packages 2003a and 2003b, the semiconductor chips 2200 may be electrically connected to each other through a connection structure including Through Silicon Via (TSV) instead of a bonding wire type connection structure 2400.

In some embodiments, the main controller 2002 and the semiconductor chips 2200 may be included in one package. In some embodiments, the main controller 2002 and the semiconductor chips 2200 may be mounted on a separate interposer substrate different from the main substrate 2001, and the main controller 2002 and the semiconductor chips 2200 may be connected to each other through wiring formed on the interposer substrate.

In some embodiments, the package substrate 2100 may be a printed circuit board. The package substrate 2100 may include a package substrate body portion 2120, the package upper pads 2130 disposed on an upper surface of the package substrate body portion 2120, lower pads 2125 disposed on a lower surface of the package substrate body portion 2120 or exposed through the lower surface, and internal wires 2135 electrically connecting the package upper pads 2130 and the lower pads 2125 inside the package substrate body portion 2120. The package upper pads 2130 may be electrically connected to the connection structures 2400. The lower pads 2125 may be connected to the wiring patterns 2005 of the main substrate 2001 of the electronic system 2000 through conductive connections 2800, as illustrated in FIG. 20.

In an electronic system according to some embodiments, each of the semiconductor chips 2200 may include the semiconductor memory device described above with reference to FIGS. 1 to 18. For example, each of the semiconductor chips 2200 may include the peripheral circuit structure PERI and the cell structure CELL stacked on the peripheral circuit structure PERI. For example, the peripheral circuit structure PERI may include the peripheral circuit substrate 300 and the peripheral circuit wiring structure 380 described above with reference to FIGS. 1 to 18. In addition, for example, the cell structure CELL may include the first substrate 100, the first mold structure MS1, the second mold structure CH2, the first string gate contact 150, the second string gate contact 250, the first through via 260, the second through via 270, the first word line contact 175, the second word line contact 275, etc. described above with reference to FIGS. 1 to 18.

Although certain embodiments of the present disclosure have been described with reference to the accompanying drawings, those of ordinary skill in the art to which the present disclosure pertains will understand that the present disclosure may be implemented in other specific forms without changing its technical idea or essential features. Therefore, it should be understood that the embodiments described above are illustrative and non-limiting in all respects.

1. A semiconductor memory device, comprising:
a first substrate comprising a first surface and a second surface opposite the first surface;
a first mold structure comprising a plurality of first gate electrodes on the second surface of the first substrate and a plurality of first string gate electrodes on the plurality of first gate electrodes;
a first interlayer insulating film on the first mold structure;
a first string gate contact extending into the first interlayer insulating film and electrically connected to one of the plurality of first string gate electrodes;
a second substrate on the first interlayer insulating film and comprising a third surface opposite the second surface, and a fourth surface opposite the third surface;
a second mold structure comprising a plurality of second gate electrodes on the fourth surface of the second substrate and a plurality of second string gate electrodes on the plurality of second gate electrodes;
a second interlayer insulating film on the second mold structure;
a second string gate contact extending into the second interlayer insulating film and electrically connected to one of the plurality of second string gate electrodes; and
a first through via extending into the second substrate and the second mold structure in a first direction perpendicular to the fourth surface of the second substrate and electrically connected to the first string gate contact and the second string gate contact.

2. The semiconductor memory device according to claim 1, wherein the plurality of second string gate electrodes comprise a first staircase shape of steps with respective pad portions, and
wherein the second string gate contact is on a pad portion of the pad portions.

3. The semiconductor memory device according to claim 2, wherein the second mold structure further comprises a plurality of dummy string electrodes on the plurality of second gate electrodes,
wherein a lowermost dummy string electrode of the plurality of dummy string electrodes is a same distance from the second substrate in the first direction as a lowermost second string gate electrode of the plurality of second string gate electrodes, and
wherein the plurality of dummy string electrodes comprises a second staircase shape of steps with respective dummy pad portions beneath the second interlayer insulating film.

4. The semiconductor memory device according to claim 3, further comprising:
a word line contact electrically connected to the plurality of second gate electrodes,
wherein the first through via is between the word line contact and the dummy pad portion.

5. The semiconductor memory device according to claim 3, wherein the first through via extends through the dummy pad portion.

6. The semiconductor memory device according to claim 3, wherein the first through via extends through the pad portion.

7. The semiconductor memory device according to claim 6, wherein the second string gate contact exists in plurality,
wherein each of the plurality of second string gate contacts electrically connects to a respective second string gate electrode of the plurality of second string gate electrodes, and
wherein the first through via is between adjacent ones of the plurality of second string gate contacts.

8. The semiconductor memory device according to claim 1, further comprising:
a wiring insulating film on the first interlayer insulating film;
a first bonding pad on an upper surface of the wiring insulating film; and
a second bonding pad on the third surface of the second substrate and electrically connected to the first bonding pad.

9. The semiconductor memory device according to claim 8, further comprising:
a wiring structure in the wiring insulating film,
wherein the wiring structure electrically connects one of the plurality of first string gate electrodes to the first through via.

10. The semiconductor memory device according to claim 1, further comprising:
a first word line contact electrically connected to one of the plurality of first gate electrodes and extending in the first direction,
wherein the first word line contact extends through a portion of the first mold structure and above at least one first gate electrode of the plurality of first gate electrodes.

11. The semiconductor memory device according to claim 10, further comprising:
a second word line contact electrically connected to one of the plurality of second gate electrodes, extending in the first direction, and extending through a portion of the second mold structure and above at least one second gate electrode of the plurality of second gate electrodes; and
a second through via extending into the second mold structure and electrically connecting the first word line contact and the second word line contact.

12. The semiconductor memory device according to claim 1, wherein a width of the first through via in a second direction parallel to the third surface of the second substrate increases as a distance from the second substrate in the first direction increases.

13. The semiconductor memory device according to claim 1, further comprising:
a first channel structure extending into the first mold structure; and
a second channel structure extending into the second mold structure,
wherein the first channel structure and the second channel structure are spaced apart from each other in the first direction.

14. A semiconductor memory device, comprising:
a first substrate;
a first mold structure comprising a plurality of first gate electrodes and a plurality of first string gate electrodes on the first substrate;
a first interlayer insulating film on the first mold structure;
a first string gate contact extending into the first interlayer insulating film and electrically connected to one of the plurality of first string gate electrodes;
a second substrate on the first interlayer insulating film and comprising a cell array region, an extension region, and a selection string region between the cell array region and the extension region;
a second mold structure comprising a plurality of second gate electrodes and a plurality of second string gate electrodes on the second substrate, the plurality of second string gate electrodes comprise a staircase shape of steps on the selection string region and comprising respective pad portions;
a second interlayer insulating film on the second mold structure;
a second string gate contact on one of the pad portions of one of the plurality of second string gate electrodes, the second string gate contact extending into the second interlayer insulating film, and electrically connected to one of the plurality of second string gate electrodes;
a first through via extending into the second substrate and the second mold structure and electrically connecting the first string gate contact and the second string gate contact; and
a first word line contact on the extension region, extending through a portion of the second mold structure, and electrically connected to one of the plurality of second gate electrodes.

15. The semiconductor memory device according to claim 14, wherein the second substrate further comprises a through region between the selection string region and the extension region, and
wherein the first through via is on the through region.

16. The semiconductor memory device according to claim 14, wherein the first through via is on the selection string region.

17. The semiconductor memory device according to claim 14, wherein the second mold structure further comprises a plurality of dummy string electrodes on the selection string region, wherein a lowermost dummy string electrode is a same distance from the second substrate in a first direction perpendicular to an upper surface of the second substrate as a lowermost second string gate electrode of the plurality of second string gate electrodes,
wherein the plurality of dummy string electrodes are spaced apart from each other in a second direction perpendicular to the first direction, and
wherein the first through via extends into the plurality of dummy string electrodes.

18. The semiconductor memory device according to claim 14, further comprising:
a second word line contact extending through a portion of the first mold structure and electrically connected to one of the plurality of first gate electrodes; and
a second through via extending into the second mold structure and electrically connecting the first word line contact and the second word line contact,
wherein the first word line contact and the second through via are on the extension region.

19. The semiconductor memory device according to claim 14, wherein a length in a direction parallel to an upper surface of the second substrate of the first through via is greater than a length in a direction parallel to an upper surface of the second substrate of the second string gate contact.

20. An electronic system, comprising:
a main substrate;
a semiconductor memory device on the main substrate, comprising a peripheral circuit structure and a cell structure on the peripheral circuit structure; and
a controller on the main substrate and electrically connected to the semiconductor memory device,
wherein the cell structure comprises:
a first substrate comprising a first surface and a second surface opposite the first surface;
a first mold structure comprising a plurality of first gate electrodes on the second surface of the first substrate, and a plurality of first string gate electrodes on the plurality of first gate electrodes;
a first interlayer insulating film on the first mold structure;
a first string gate contact extending into the first interlayer insulating film and electrically connected to one of the plurality of first string gate electrodes;
a second substrate on the first interlayer insulating film and comprising a third surface opposite to the second surface, and a fourth surface opposite to the third surface;
a second mold structure comprising a plurality of second gate electrodes on the fourth surface of the second substrate, and a plurality of second string gate electrodes on the plurality of second gate electrodes, the plurality of second string gate electrodes comprising a staircase shape of steps and with respective pad portions;
a second interlayer insulating film on the second mold structure;
a second string gate contact on one of the pad portions of one of the plurality of second string gate electrodes, the second string gate contact extending into the second interlayer insulating film and electrically connected to one of the plurality of second string gate electrodes; and
a first through via extending into the second substrate and the second mold structure, extending in a direction perpendicular to the fourth surface of the second substrate, and electrically connected to the first string gate contact and the second string gate contact.
